(19) United States
(12) Patent Application Publication
(10) Pub. No.: US 2025/0185303 A1
(43) Pub. Date: Jun. 5, 2025

(54) COMPRESSIVE STRAIN IN STACKED NANOSHEET FIELD EFFECT TRANSISTOR

(71) Applicant: International Business Machines Corporation, Armonk, NY (US)

(72) Inventors: Takashi Ando, Eastchester, NY (US); Guy M. Cohen, Westchester, NY (US); Nanbo Gong, White Plains, NY (US)

(21) Appl. No.: 18/527,971

(22) Filed: Dec. 4, 2023

(51) Int. Cl. H01L 29/49; H01L 21/28; H01L 21/8238; H01L 27/092; H01L 29/06; H01L 29/423; H01L 29/66; H01L 29/775

(52) U.S. Cl. CPC H10D 30/6739; H01L 21/28088; H10D 30/014; H10D 30/43; H10D 30/6735; H10D 62/121; H10D 64/017; H10D 84/0177; H10D 84/038; H10D 84/85

(57) ABSTRACT

Embodiments disclosed herein include a semiconductor structure. The semiconductor structure may include an NFET transistor with NFET nanosheets and a first workfunction setting metal that is pinched off within spaces between the NFET nanosheets and a PFET transistor with PFET nanosheets surrounded by a thin layer of a second workfunction setting metal. The semiconductor structure may also include a doped metal between the PFET nanosheets surrounded by a thin layer of a workfunction setting metal.

### BACKGROUND

The present invention relates generally to the field of semiconductor device fabrication, and more particularly to fabricating a doped metal around nanosheets of a transistor that provides compressive strain.

Nanosheet field-effect transistors (FETs) are key components in advanced semiconductor technology, and strain engineering is a critical technique used to enhance their performance. By applying controlled mechanical strain to the transistor channel, engineers can improve carrier mobility for both electrons and holes, leading to faster switching speeds and overall higher transistor performance. This enhanced mobility allows charge carriers to move more efficiently through the channel, resulting in better current drive and reduced leakage current, which is crucial for power efficiency in electronic devices.

Moreover, channel strain engineering can effectively modulate the threshold voltage of nanosheet FETs. This threshold voltage determines the voltage level required to turn the transistor on or off. Through strain manipulation, engineers can tailor this parameter to optimize the transistor's performance for specific applications. Furthermore, strain engineering often complements other techniques, such as high-k dielectrics and metal gate materials, to further boost nanosheet FET performance.

### SUMMARY

Aspects of an embodiment of the present invention include a semiconductor structure. The semiconductor structure may include an NFET transistor with NFET nanosheets and a first workfunction setting metal that is pinched off within spaces between the NFET nanosheets and a PFET transistor with PFET nanosheets surrounded by a thin layer of a second workfunction setting metal. The semiconductor structure may also include a doped metal between the PFET nanosheets surrounded by a thin layer of a workfunction setting metal.

Aspects of an embodiment of the present invention encompass a method of fabricating a semiconductor structure. The method may include depositing a host metal around nanosheets of a PFET transistor and doping the host metal to form a doped metal that compresses the nanosheets of the PFET transistor.

Aspects of an embodiment of the present invention include a semiconductor structure. The semiconductor structure may include a first nanosheet of a PFET transistor, a second nanosheet of the PFET transistor, and a doped metal around the first nanosheet, around the second nanosheet, and between the first nanosheet and the second nanosheet.

### BRIEF DESCRIPTION OF THE DRAWINGS

FIG. 1 depicts a schematic top view of a semiconductor structure 100, in accordance with one embodiment of the present invention.

FIGS. 2A and 2B depict cross-sectional side views of the semiconductor structure of FIG. 1 at a fabrication stage, in accordance with one embodiment of the present invention.

FIGS. 3A and 3B depict cross-sectional side views of the semiconductor structure of FIG. 1 at a fabrication stage, in accordance with one embodiment of the present invention.

FIGS. 4A and 4B depict cross-sectional side views of the semiconductor structure of FIG. 1 at a fabrication stage, in accordance with one embodiment of the present invention.

FIGS. 5A and 5B depict cross-sectional side views of the semiconductor structure of FIG. 1 at a fabrication stage, in accordance with one embodiment of the present invention.

FIGS. 6A and 6B depict cross-sectional side views of the semiconductor structure of FIG. 1 at a fabrication stage, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Improvements in the design of integrated circuits (IC) have enabled feature sizes for transistors in a device layer to enter into deep submicron and nanometer regime. Embodiments herein recognize benefits from strain control to improve carrier mobility. In nanosheet transistors, the mechanical strain that improves performance depends on the type of transistor. Specifically, tensile stress increases the mobility of the electrons in an NFET transistor, which improves performance due to the breaking of the crystal symmetry and removing of the 2-fold and 6-fold degeneracy of the valence and conduction bands respectively. This will lead into changes of the band scattering rates and the carrier effective mass, which in turn affect carrier mobility. Contrarily, compressive stress increases the mobility of the holes of a PFET transistor, which improves performance for similar reasons. The embodiments of semiconductor structures here control the strains (e.g., tensile and compressive strains on the nanosheets) by surrounding the nanosheets with a metal, and then doping the metal to release a strain to the nanosheet via movement of pre-existing defects, formation of new dislocations, plastic deformation, or film bucking, depending on the film thickness and the strain energies.

The embodiments below thus improve the functioning of a semiconductor structure by including an NFET transistor with NFET nanosheets and a first workfunction setting metal that is pinched off within spaces between the NFET nanosheets and a PFET transistor with PFET nanosheets surrounded by a thin layer of a second workfunction setting metal. The semiconductor structure may also include a doped metal between the PFET nanosheets surrounded by a thin layer of a workfunction setting metal. The doped metal provides the technical benefit of strain on the nanosheet that increases mobility of the holes in the PFET nanosheets, which increases responsiveness and efficiency as a result.

Certain embodiments may also include workfunction setting metals such as titanium nitride and aluminum alloy. These metals provide the technical benefit of low-defect fabrication and efficient operation of the FET devices. The doped metal in certain embodiments may include palladium, which beneficially provides a known amount of strain on the nanosheets when doped with a dopant under known conditions. The conditions and strain on the nanosheets may be adjusted by adjusting the temperature, pressure, and time under which the dopant is applied to the palladium. The doped metal may doped with hydrogen in certain embodiments. The hydrogen provides known amounts of strain on the nanosheets, which may be adjusted by adjusting the temperature, pressure, and time under which the hydrogen is applied to the doped metal. In certain embodiments, the NFET nanosheets may include a first interfacial layer and a first high-K layer beneath the first workfunction setting metal and the PFET nanosheets may include a second interfacial layer and a second high-k layer beneath the second workfunction setting metal. These layers provide the technical benefit of increased efficiency of the electric interaction between the nanosheets and the workfunction setting metals. In certain embodiments, the semiconductor structures may include a fill metal around the doped metal. The fill metal may fill a replacement metal gate trench between a first source/drain (S/D) and a second S/D. The fill metal provides the technical benefit of holding the doped metal in place so that the doping may occur in a controlled manner, and the strain provided by the doped metal may remain consistent after fabrication is completed. In certain embodiments, the nanosheets may include a thickness between 2 nanometers and 9 nanometers, and a separation distance between the nanosheets between 5 and 15 nanometers to provide space for the host metal and other layers to fit between the nanosheets without increasing the size of the overall semiconductor structure.

Certain embodiments of the present invention may be manifested as methods of fabricating a semiconductor structure. Embodiments of such methods may include depositing a host metal around nanosheets of a PFET transistor and doping the host metal to form a doped metal that compresses the nanosheets of the PFET transistor. The doped metal provides the technical benefit of strain on the nanosheet that increases mobility of the holes or the electrons in the FET nanosheets, which increases responsiveness and efficiency as a result. In certain embodiments, doping the host metal may include annealing the host metal with a dopant at a pressure over five atmospheres and a temperature over 200 Celsius. This combination of temperatures and pressures provides the benefit of speed and accuracy of the doping process, which in turn provides known strain amounts as applied to the nanosheets.

Certain embodiments of the present invention may include semiconductor structures. Such embodiments may include a first nanosheet of a PFET transistor, a second nanosheet of the PFET transistor, and a doped metal around the first nanosheet, around the second nanosheet, and between the first nanosheet and the second nanosheet. The doped metal provides the technical benefit of strain on the nanosheet that increases mobility of the holes in the PFET nanosheets, which increases responsiveness and efficiency as a result. Certain embodiments may further include a first nanosheet of an NFET transistor, a second nanosheet of the NFET transistor, and an NFET workfunction setting metal surrounding the first nanosheet of the NFET transistor and the second nanosheet of the NFET transistor. The NFET workfunction setting metal pinches off between the first nanosheet of the NFET transistor and the second nanosheet of the NFET transistor. These embodiments provide the technical benefit of increased responsiveness and efficiency to the PFET nanosheets without negatively impacting the NFET nanosheets.

The present invention and an example fabrication process will now be described in detail with reference to the Figures.

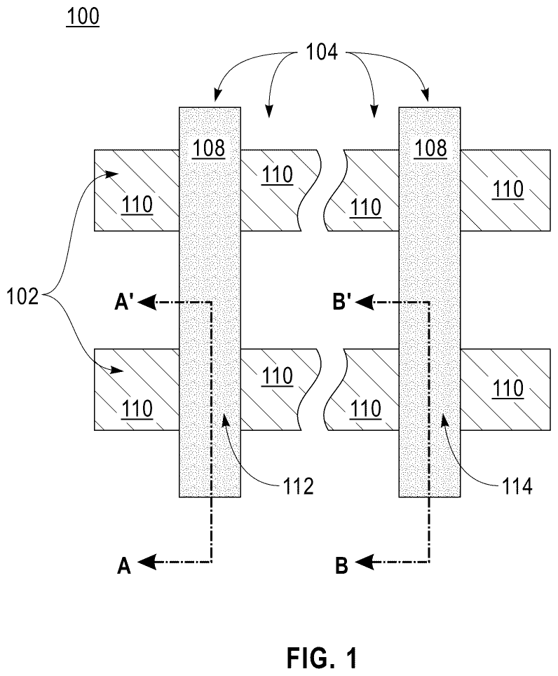

FIG. 1 depicts a schematic top view of a semiconductor structure 100, in accordance with one embodiment of the present invention. The semiconductor structure 100 includes rows 102 of field-effect transistor (FET) devices and columns 104 of gate and source/drains (S/Ds) fabricated in a device layer of the semiconductor structure 100. The columns 104 include gates 108 that control channels between S/Ds 110. The semiconductor structure 100 will eventually include contacts to electrically connect certain of the S/Ds 110 to back-end-of-line (BEOL) interconnect structures. The semiconductor structure 100 includes other components (e.g., shallow trench isolation, interlayer dielectric) that are not illustrated in FIG. 1 so that the rows and columns of the semiconductor structure 100 may be more easily described.

The semiconductor structure 100 includes an NFET transistor 112 and a PFET transistor 114 that may be formed on the same structure (e.g., wafer) but located on any row 102 or column 104. The NFET transistor 112 (and fabrication steps) are illustrated in the “A” Figures below (2A, 3A, etc.) representing a cross-sectional view along the line A-A′ here in FIG. 1. The PFET transistor 114 (and fabrication steps) are illustrated in the “B” Figures below (2B, 3B, etc.) representing a cross-sectional view along the line B-B′ here in FIG. 1.

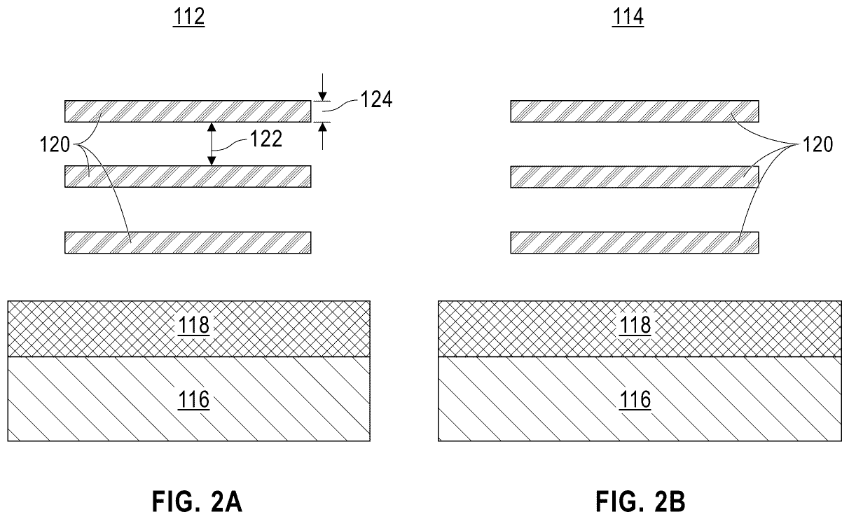

FIGS. 2A and 2B depict cross-sectional side views of the semiconductor structure 100 of FIG. 1 at a fabrication stage, in accordance with one embodiment of the present invention. As explained above, FIG. 2A is a cross-sectional side view of one column 104 (i.e., the NFET transistor 112) of the semiconductor structure 100 along line A-A′ of FIG. 1; and FIG. 2B is a cross-sectional side view of another column 104 (i.e., the PFET transistor 114) of the semiconductor structure 100 along line B-B′ of FIG. 1. Each of these views is a cross-section of a replacement metal gate trench between a first S/D 110 and a second S/D 110 for each of the transistors 112, 114.

The semiconductor structure 100 includes a substrate 116 typically formed of silicon. Above the substrate 116 is a dielectric isolation layer 118 that isolates the substrate 116 from nanosheets 120 that are formed as blanket layers above the dielectric isolation layer 118. The stage shown in FIGS. 2A and 2B shows the result after the blanket layers have been etched into fins, and then the dummy layers between the nanosheets 120 have been released. The releasing and removal of the dummy layers leaves a separation distance 122 that may be greater than a thickness 124 of the nanosheets 120. For example, the separation distance 122 may be between 5 and 15 nanometers while the thickness 124 may be between 2 and 9 nanometers.

The releasing of the dummy layers suspends the nanosheets 120, with the only support provided at either end of the nanosheets 120. That is, the nanosheets 120 are supported at a first end (going into the page) toward a first S/D 110 and at a second end (coming out of the page) toward a second S/D 110. Besides the first end and second end, the nanosheets 120 are unsupported, which negates any strain that was, or potentially could have been, introduced during the forming of the nanosheets 120 as layers. That is, even if the nanosheets 120 are epitaxially grown as strained-silicon, the straining is reduced or negated when the dummy layers are released. The doped metal, formed for example using the process below, introduces beneficial strain back into the nanosheets 120.

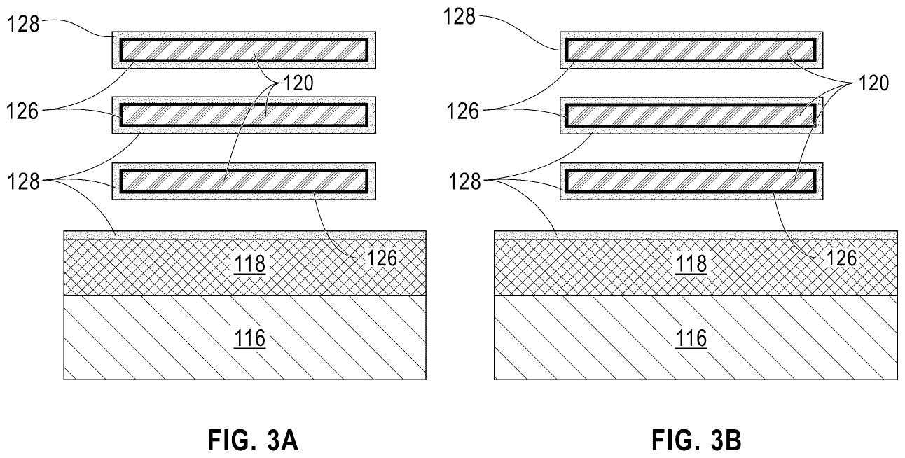

FIGS. 3A and 3B depict cross-sectional side views of the semiconductor structure 100 of FIG. 1 at a fabrication stage, in accordance with one embodiment of the present invention. The nanosheets 120 have been clad in an interfacial layer 126 and a high-K layer 128. The material and dimensional characteristics of the interfacial layer 126 determine the electrical performance and reliability of the nanosheets 120, as these characteristics affect the threshold voltage, subthreshold swing, mobility, and interface trap density. The interfacial layer 126 can be formed by various methods, such as thermal oxidation, atomic layer deposition, or plasma-enhanced chemical vapor deposition. The choice of the interfacial layer 126 material and the formation technique depends on the compatibility with the material of the nanosheets 120, the desired electrical properties, and the fabrication process. The high-K layer 128 is a thin film of metal oxide, formed for example using atomic layer deposition, that is used to reduce the leakage current and improve the performance of the nanosheets 120. That is, the high-k layer 128 acts as the gate dielectric, which controls the flow of charge carriers in the channel. Both the interfacial layer 126 and the high-K layer 128 are formed around the nanosheets 120, but the interfacial layer 126 and the high-K layer 128 do not contact each other so that a separation distance is maintained between the nanosheets 120. The separation distance 122 is reduced by presence of the interfacial layer and the HKMG 128, but may still remain in a range between 3 and 10 nanometers.

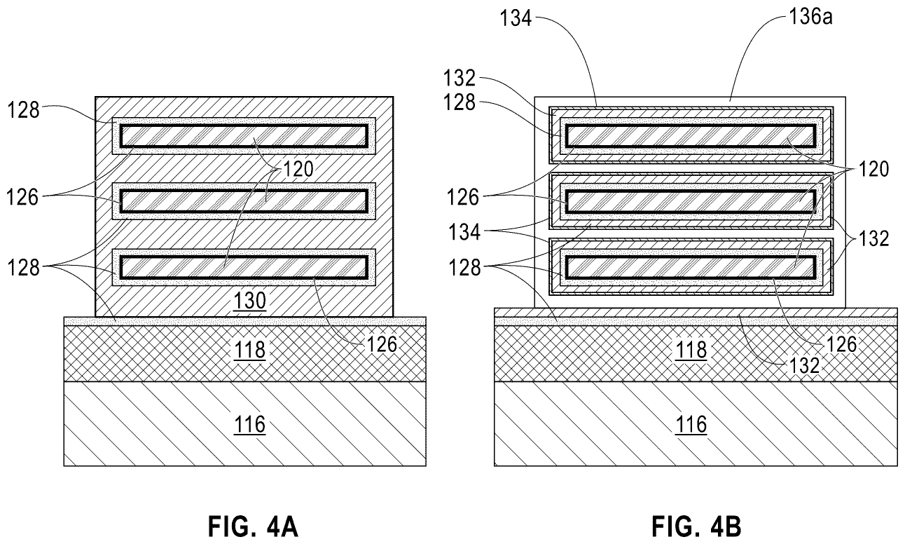

FIGS. 4A and 4B depict cross-sectional side views of the semiconductor structure 100 of FIG. 1 at a fabrication stage, in accordance with one embodiment of the present invention. The semiconductor structure 100 includes a NFET workfunction metal 130 and a PFET workfunction metal 132 that are deposited around the nanosheets 120 on the outside of the high-K layer 128. The NFET workfunction metal 130 is deposited first with a thickness that pinches off within spaces between the nanosheets. Then the NFET transistor 112 may be masked while the NFET workfunction metal 130 is removed from the PFET transistor 114 and then PFET workfunction metal 132 is deposited. The PFET workfunction metal 132 may be deposited at a different thickness than the NFET workfunction metal 130, with the NFET workfunction metal 130 being deposited thickly enough to pinch off within spaces between the nanosheets 120. That is, the deposition thickness of the NFET workfunction metal 130 may be greater than half of the separation distance 122 after the formation of the HKMG 128. The separation distance 122 for the NFET transistor 112 is thus eliminated, and the NFET workfunction metal 130 completely encloses all of the nanosheets 120 in the NFET nanosheet stack.

The PFET workfunction metal 132 then has an electrode layer 134 (e.g., 1 nanometer) deposited around the exposed exterior. The electrode layer 134 contributes to successful low threshold operation, which means the PFET transistor 114 is able to be activated with less voltage. The electrode layer 134 may be titanium nitride (TiN) deposited using atomic layer deposition.

Following the electrode layer 134, the semiconductor structure 100 has a host metal 136a deposited around the nanosheets 120, which fills the separation distance 122 and completely surround the nanosheet stack of the PFET transistor 114. The host metal 136a may include, for example, palladium, the deposition of which leaves no gaps between the nanosheets 120, such that the nanosheets 120 are each surrounded by the host metal 136a. After the deposition of the host metal 136a, it may be removed from the NFET transistor 112 while masking the PFET transistor 114host metal.

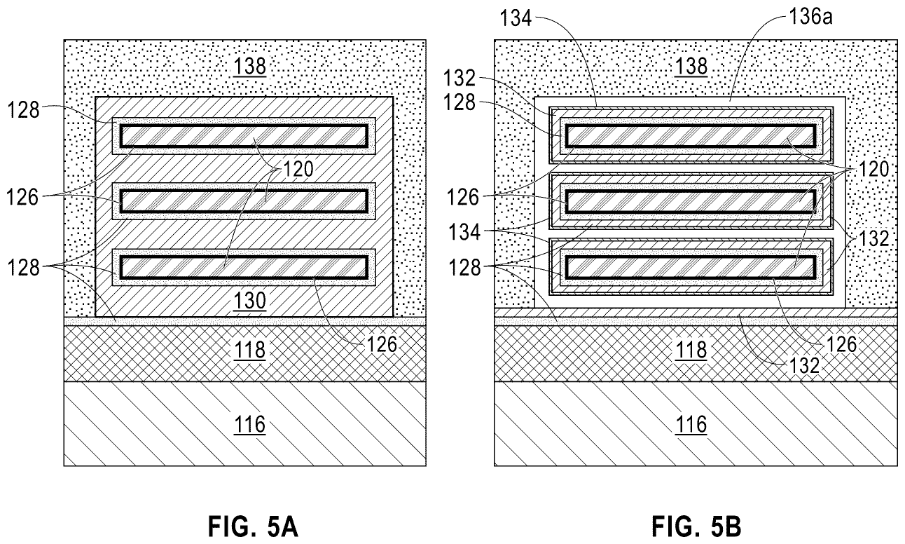

FIGS. 5A and 5B depict cross-sectional side views of the semiconductor structure 100 of FIG. 1 at a fabrication stage, in accordance with one embodiment of the present invention. The semiconductor structure 100 includes a fill metal 138 that fills the replacement metal gate trenches between the first S/D 110 and the second S/D 110 of each of the NFET transistor 112 and the PFET transistor 114. The fill metal 138 can be deposited by chemical vapor deposition (CVD) or atomic layer deposition (ALD) in a conformal manner. CVD or ALD can deposit various metals, such as tungsten, cobalt, or platinum, with high uniformity. The fill metal 138 is then smoothed using chemical-mechanical polishing techniques.

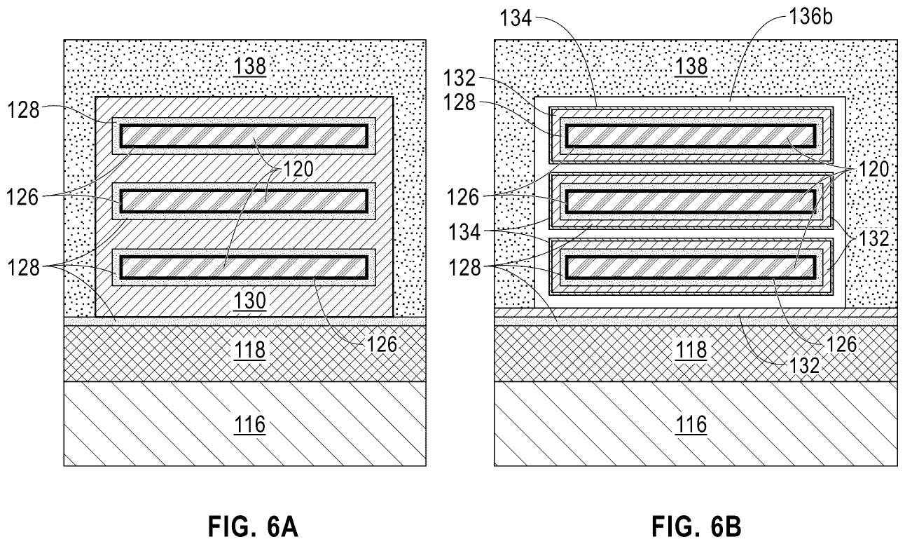

FIGS. 6A and 6B depict cross-sectional side views of the semiconductor structure 100 of FIG. 1 at a fabrication stage, in accordance with one embodiment of the present invention. The semiconductor structure 100 is subjected to a doping process that changes the host metal 136a to a doped metal 136b containing a dopant that results in a compression strain in the nanosheets 120 of the PFET transistor 114. Doping is a process of introducing impurities into the structure of the material to change certain properties. The dopant in the doped metal 136b may be hydrogen. Doping the doped metal 136b with hydrogen involves introducing hydrogen atoms into the interstitial sites of the metal lattice. This can result in a non-stoichiometric mixture, meaning that the ratio of metal and hydrogen cannot be represented by a natural number. The dopant can have various effects, such as changing the lattice expansion, resistance, magnetic properties, and hydrogen permeability of the metal. It can also enhance the electrocatalytic reduction of aqueous CO2 to CO by suppressing the undesired hydrogen evolution reaction. Depending on the type and amount of the dopant, the doped metal 136b imparts a strain (i.e., compressive or tensile) onto the nanosheets 120.

In certain embodiments, the doped metal 136b may be doped using a high pressure annealing process. High pressure annealing usually takes place at pressures above five atmospheres, and temperatures above 200 Celsius. The pressure, temperature, and time at which the semiconductor structure 100 is annealed may be adjusted to control the amount of doping. In certain embodiments, the high pressure annealing involves temperatures between 375 Celsius and 525 Celsius with a pressure between 8 atmospheres and 15 atmospheres. The time of annealing may take between 15 and 60 minutes. Other combinations of temperature, pressure, and time may also be used without diverging from the embodiments disclosed herein. The doped metal 136b thus imparts a compressive strain on the nanosheets 120 such that a center of the nanosheets 120 (i.e., the portion shown in the cross-sectional views) shrinks, and each end is compressed from the S/Ds 110 toward the center.

Conventional contact formation and other finishing processes may be used on the semiconductor structure 100 following the stage illustrated in FIGS. 6A and 6B.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections and buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
an NFET transistor comprising NFET nanosheets and a first workfunction setting metal pinched off within spaces between the NFET nanosheets;
a PFET transistor comprising:
PFET nanosheets surrounded by a thin layer of a second workfunction setting metal; and
a doped metal between the PFET nanosheets surrounded by a thin layer of a workfunction setting metal.

2. The semiconductor structure of claim 1, wherein the first workfunction setting metal and the second workfunction setting metal comprise a selection from the group consisting of: titanium nitride and aluminum alloy.

3. The semiconductor structure of claim 1, wherein the doped metal comprises palladium.

4. The semiconductor structure of claim 1, wherein the doped metal is doped with hydrogen.

5. The semiconductor structure of claim 1, wherein:
the NFET nanosheets comprise a first interfacial layer and a first high-k layer beneath the first workfunction setting metal; and
the PFET nanosheets comprise a second interfacial layer and a second high-K layer beneath the second workfunction setting metal.

6. The semiconductor structure of claim 1, further comprising a fill metal around the doped metal, wherein the fill metal fills a replacement metal gate trench between a first source/drain (S/D) and a second S/D.

7. The semiconductor structure of claim 1, wherein the nanosheets comprise a thickness between 2 nanometers and 9 nanometers, and a separation distance between the nanosheets is between 5 and 15 nanometers.

8. A method of fabricating a semiconductor structure, comprising:
depositing a host metal around nanosheets of a PFET transistor;
doping the host metal to form a doped metal that compresses the nanosheets of the PFET transistor.

9. The method of claim 8, wherein the doped metal comprises palladium doped with hydrogen.

10. The method of claim 8, further comprising filling a replacement metal gate trench with a fill metal before doping the host metal.

11. The method of claim 8, further comprising depositing an interfacial layer, a high-K metal gate layer, and a PFET workfunction metal layer around the nanosheets before depositing the host metal.

12. The method of claim 8, wherein doping the host metal comprises annealing the host metal with a dopant at a pressure over five atmospheres and a temperature over 200 Celsius.

13. The method of claim 8, further comprising forming an NFET workfunction metal around the nanosheets of an NFET transistor of the semiconductor structure.

14. A semiconductor structure, comprising:
a first nanosheet of a PFET transistor;
a second nanosheet of the PFET transistor;
a doped metal around the first nanosheet, around the second nanosheet, and between the first nanosheet and the second nanosheet.

15. The semiconductor structure of claim 14, wherein the doped metal comprises palladium.

16. The semiconductor structure of claim 14, wherein the doped metal is doped with hydrogen.

17. The semiconductor structure of claim 14, further comprising a workfunction setting metal surrounding the first nanosheet, wherein the workfunction metal is between the first nanosheet and the doped metal.

18. The semiconductor structure of claim 14, further comprising:
a first nanosheet of an NFET transistor;
a second nanosheet of the NFET transistor; and
an NFET workfunction setting metal surrounding the first nanosheet of the NFET transistor and the second nanosheet of the NFET transistor, wherein the NFET workfunction setting metal pinches off between the first nanosheet of the NFET transistor and the second nanosheet of the NFET transistor.

19. The semiconductor structure of claim 18, further comprising a PFET workfunction setting metal, wherein the PFET workfunction setting metal and the NFET workfunction setting metal comprise a same elemental material.

20. The semiconductor structure of claim 14, further comprising a fill metal around the doped metal, wherein the fill metal fills a replacement metal gate trench.
